(19) United States
(12) Patent Application Publication
(10) Pub. No.: US 2025/0209240 A1
(43) Pub. Date: Jun. 26, 2025

(54) DEEP LEARNING SIMULATION OF TOPOLOGICAL INSULATOR

(71) Applicants: Beijing Youzhuju Network Technology Co., Ltd., Beijing (CN); Bytedance Technology Ltd., Grand Cayman (KY)

(72) Inventors: Xiang Li, Beijing (CN); Yixiao Chen, Los Angeles, CA (US); Haoxiang Chen, Beijing (CN); Weiluo Ren, Beijing (CN); Ji Chen, Beijing (CN)

(21) Appl. No.: 19/077,765

(22) Filed: Mar. 12, 2025

(51) Int. Cl. G06F 30/27

(52) U.S. Cl. CPC G06F 30/27

(57) ABSTRACT

A method is proposed for a deep learning simulation of a topological insulator. The method includes determining, by using a neural network, a wavefunction of a moiré system based on positions and spins of electrons of the moiré system; and determining, based on the wavefunction, whether the moiré system is a topological insulator.

### FIELD

The present disclosure generally relates to the field of computers, and more specifically, to methods, devices, and computer program products for a deep learning simulation of a topological insulator.

### BACKGROUND

Topological insulators, which exhibit unique electronic properties protected by topology, hold immense promise for next-generation electronic devices. However, unraveling their complex quantum phases, especially at larger scales and fractional fillings, poses a significant challenge.

### SUMMARY

In a first aspect of the present disclosure, there is provided a method for deep learning simulation of a topological insulator. The method comprises determining, by using a neural network, a wavefunction of a moiré system based on positions and spins of electrons of the moiré system; and determining, based on the wavefunction, whether the moiré system is a topological insulator.

In a second aspect of the present disclosure, there is provided an electronic device. The electronic device comprises: a computer processor coupled to a computer-readable memory unit, the memory unit comprising instructions that when executed by the computer processor implements a method according to the first aspect of the present disclosure.

In a third aspect of the present disclosure, there is provided a computer program product, the computer program product comprising a computer readable storage medium having program instructions embodied therewith, the program instructions executable by an electronic device to cause the electronic device to perform a method according to the first aspect of the present disclosure.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Through the more detailed description of some embodiments of the present disclosure in the accompanying drawings, the above and other objects, features, and advantages of the present disclosure will become more apparent, wherein the same reference generally refers to the same components in the embodiments of the present disclosure.

FIG. 1 illustrates a schematic diagram of an example process 100 of a deep learning simulation of a topological insulator according to some embodiments of the present disclosure;

FIG. 2 illustrates an overview of an example deep learning simulation of a topological insulator according to some embodiments of the present disclosure;

FIG. 3 illustrates examples of calculated phase diagrams of integer topological insulators according to some embodiments of the present disclosure;

FIG. 4 illustrates examples of calculated energy spectrums of fractional Chern insulator (FCI) according to some embodiments of the present disclosure;

FIG. 5 illustrates example results of FCI-charge density wave (CDW) competing according to some embodiments of the present disclosure;

FIG. 6 illustrates an example flowchart of a method for a deep learning simulation of a topological insulator according to some embodiments of the present disclosure; and

FIG. 7 illustrates a block diagram of an electronic device in which various embodiments of the present disclosure can be implemented.

### DETAILED DESCRIPTION

Principle of the present disclosure will now be described with reference to some embodiments. It is to be understood that these embodiments are described only for the purpose of illustration and help those skilled in the art to understand and implement the present disclosure, without suggesting any limitation as to the scope of the disclosure. The disclosure described herein can be implemented in various manners other than the ones described below.

In the following description and claims, unless defined otherwise, all technical and scientific terms used herein have the same meaning as commonly understood by one of ordinary skills in the art to which this disclosure belongs.

References in the present disclosure to “one embodiment,” “an embodiment,” “an example embodiment,” and the like indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an example embodiment, it is submitted that it is within the knowledge of one skilled in the art to affect such feature, structure, or characteristic in connection with other embodiments whether or not explicitly described.

It shall be understood that although the terms “first” and “second” etc. may be used herein to describe various elements, these elements should not be limited by these terms. These terms are only used to distinguish one element from another. For example, a first element could be termed a second element, and similarly, a second element could be termed a first element, without departing from the scope of example embodiments. As used herein, the term “and/or” includes any and all combinations of one or more of the listed terms.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components etc., but do not preclude the presence or addition of one or more other features, elements, components and/or combinations thereof.

Principle of the present disclosure will now be described with reference to some embodiments. It is to be understood that these embodiments are described only for the purpose of illustration and help those skilled in the art to understand and implement the present disclosure, without suggesting any limitation as to the scope of the disclosure. The disclosure described herein can be implemented in various manners other than the ones described below. In the following description and claims, unless defined otherwise, all technical and scientific terms used herein have the same meaning as commonly understood by one of ordinary skills in the art to which this disclosure belongs.

It may be understood that data involved in the present technical solution (including but not limited to the data itself, the acquisition or use of the data) should comply with requirements of corresponding laws and regulations and relevant rules.

It may be understood that, before using the technical solutions disclosed in various embodiment of the present disclosure, the user should be informed of the type, scope of use, and use scenario of the information involved in the present disclosure in an appropriate manner in accordance with relevant laws and regulations, and the user's authorization should be obtained.

For example, in response to receiving an active request from the user, prompt information is sent to the user to explicitly inform the user that the requested operation will need to acquire and use the user's information. Therefore, the user may independently choose, according to the prompt information, whether to provide the information to software or hardware such as electronic devices, applications, servers, or storage media that perform operations of the technical solutions of the present disclosure.

As an optional but non-limiting implementation, in response to receiving an active request from the user, the way of sending prompt information to the user, for example, may include a pop-up window, and the prompt information may be presented in the form of text in the pop-up window. In addition, the pop-up window may also carry a selection control for the user to choose “agree” or “disagree” to provide the information to the electronic device.

It may be understood that the above process of notifying and obtaining the user authorization is only illustrative and does not limit the implementation of the present disclosure. Other methods that satisfy relevant laws and regulations are also applicable to the implementation of the present disclosure.

As used herein, the term “model” is referred to as an association between an input and an output learned from training data, and thus a corresponding output may be generated for a given input after the training. The generation of the model may be based on a machine learning technique. In general, a machine learning model may be built, which receives input information and makes predictions based on the input information. For example, a classification model may predict a class of the input information among a predetermined set of classes. As used herein, “model” may also be referred to as “machine learning model”, “learning model”, “machine learning network”, or “learning network,” which are used interchangeably herein.

Topological physics has emerged as a cornerstone of modern condensed matter physics, revolutionizing our understanding of quantum phases of matter. Beginning with the discovery of the quantum Hall effect (QHE) in two-dimensional electron gas, the field has expanded to encompass a wide array of topological insulators, characterized by diverse particle fillings, spatial dimensions, and symmetry properties. A significant recent advancement is the experimental realization of the fractional Chern insulator (FCI) in moiré materials. Unlike conventional QHE, which requires external magnetic fields, Chern insulators exhibit spontaneous time-reversal symmetry breaking due to intrinsic spin-orbit coupling. This unique feature not only deepens the understanding of topological phases, but also holds considerable promise for applications in low-power electronics and quantum computing.

Despite rapid experimental progress, a comprehensive theoretical understanding of FCI remains elusive. This challenge stems primarily from the flat single-particle band structure of FCI, which precludes adiabatic evolution from FCI state to a single Slater determinant and necessitates a complete solution of the energy spectrum. While exact diagonalization (ED) and density matrix renormalization group (DMRG) methods have provided valuable insights, they are hindered by impractical computational scaling, limiting their applicability to larger systems or higher accuracy. As a result, there is a pressing need for innovative theoretical tools to study strong correlation topological systems.

In recent years, deep learning quantum Monte Carlo (QMC) methods have gained traction in electronic structure problems, demonstrating superior performance over many traditional approaches. It leverages neural networks to represent the wavefunctions of quantum systems, offering a powerful framework for capturing strong correlation systems. With millions of tunable parameters, neural networks provide exceptional accuracy and flexibility, enabling the representation of complex wavefunctions that are otherwise intractable. And the combination of neural network and QMC ensure both the precision and efficiency of simulations. This approach has proven highly successful in a variety of contexts, including molecular systems, electron gas, real solids, fractional quantum hall and moiré materials. However, its applicability to topological insulators, particularly at fractional fillings, remains an open question, as the non-trivial topology and strong correlation present unique challenges for neural network representations.

Embodiments of the present disclosure propose solutions for a deep learning simulation of a topological insulator. According to embodiments of the present disclosure, a method comprises determining, by using a neural network, a wavefunction of a moiré system based on positions and spins of electrons of the moiré system; and determining, based on the wavefunction, whether the moiré system is a topological insulator. With this solution, a neural network wavefunction approach to investigate topological systems is enabled by introducing spins of the moiré system into the neural network.

Example embodiments of the present disclosure will be described in detail below with reference to the accompanying drawings.

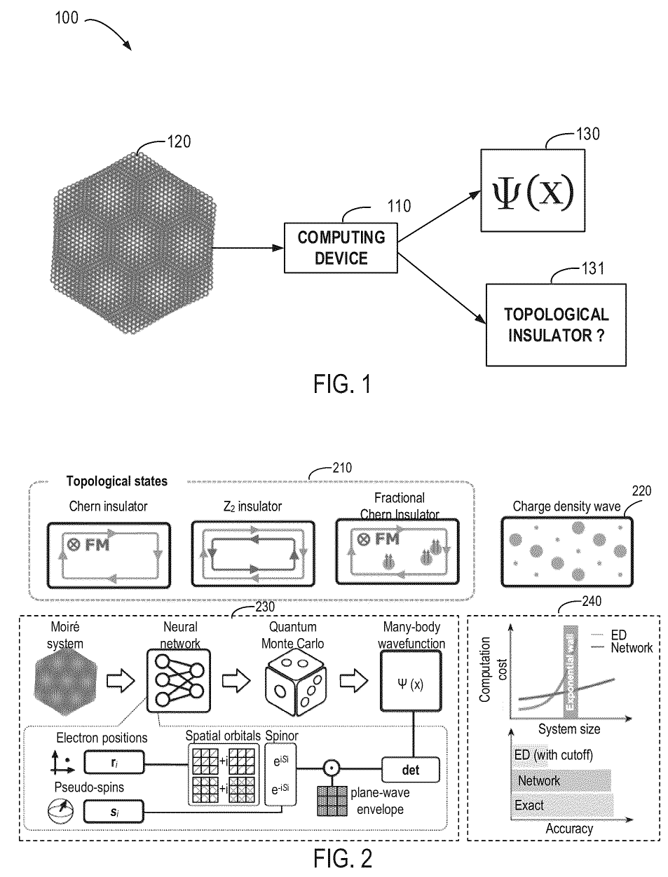

FIG. 1 illustrates a schematic diagram of an example process 100 of a deep learning simulation of a topological insulator according to some embodiments of the present disclosure. As illustrated in FIG. 1, in the process 100, a computing device 110 receives a representation of a moiré system 120 as an input. The representation of the moiré system 120 may include various parameters to represent the moiré system 120, for example, structures of the moiré system 120. The computing device 110 may output a wavefunction 130 of the moiré system 120. Alternatively or in addition, the computing device 110 may output a determination 131 that whether the moiré system 120 is a topological insulator. The computing device 110 may be any suitable device with a computing capability and the scope of the present disclosure is not limited in this regard.

Moiré systems, also referred to as moiré materials, provide an ideal platform for studying topological phases due to their tunable band structures and strong correlations. By employing a neural network to represent the wavefunction, a range of topological states can be accurately identified, such as from Chern insulators to Z2 insulators and from integer fillings to more challenging fractional fillings. Moreover, compared to traditional ED methods, the proposed solution of the present disclosure exhibits superior accuracy with predicted phases consistent with the experiments, highlighting the potential of neural network-based approaches in advancing the study of topological quantum matter. Details will be described in the following.

FIG. 2 illustrates an overview of an example deep learning simulation of a topological insulator according to embodiments of the present disclosure. FIG. 2 illustrates examples of topological insulators 210 and an example charge density wave 220 of topological insulators. As illustrated in FIG. 2, topological insulators may have different states with varying filling factors and topological properties. A Chern insulator is the topological insulator with an integer filing factor and a fractional Chern insulator (FCI) is the topological insulator with a fractional filing factor. A Z2 insulator is the topological insulator with an integer filing factor and electrons in spin-up and spin-down.

FIG. 2 also illustrates an example simulation workflow 230 according to embodiments of the present disclosure. In the simulation workflow 230, a neural network may be used to represent a many-body wavefunction of topological systems, and quantum Monte Carlo method may be employed to optimize the neural network and approach a ground state of the many-body wavefunction. In other words, a ground state of the wavefunction may be determined by using Quantum Monte Carlo and the ground state is then used for determining whether the moiré system is a topological insulator. For example, variational Monte Carlo (VMC) methods may be employed to optimize the neural network. VMC is well known for its low computational complexity O(N 4) and without sign problem, ensuring both the efficiency and accuracy of the proposed solution of the present disclosure.

FIG. 2 also illustrates an example comparison 240 between the neural network approach and ED. As can be seen from the figure, ED method may be limited by the exponential scaling of the Hilbert space, which can be circumvented by the neural network approach. Furthermore, the neural network method can achieve better accuracy compared to ED.

As discussed above, to study the topological property of various systems, a neural network is used to express corresponding wavefunctions, which may read

$${Ψ}_{Net} ( {x}_{1} , {x}_{2} , … , {x}_{n} ) = det \vert {ϕ}_{i} ( {x}_{j} ; {x}_{\neq j} ) \vert \qquad ( 1 )$$

where x represents electron's degrees of freedom, including a position and a spin. In other words, in the present disclosure, it is proposed to introduce spins of the moiré system so as to determine the wavefunction of the moiré system. The neural network is configured to determine the wavefunction based on both electron positions and spins of the moiré system. The neural network may be modified based on DeepSolid architecture, which has been proposed and employed to provide good accuracy in real solids and moiré materials, to consider both electron positions and spins of the moiré system.

The spins may comprise pseudo-spins and real-spins. The pseudo-spins may be also referred to as layer-spins in layered structures. Layer-spin variables may be introduced to mitigate sampling challenges in quantum Monte Carlo. Details of the real-spins, layer-spins and pseudo spins are omitted herein.

In some embodiments, a distance feature vector of the moiré system may be determined based on the positions of electrons. Quasi-orbitals of the moiré system may be determined based on the distance feature vector; and the wavefunction may be determined based on a first layer term and a second layer term associated with the layer-spins of electrons. The first layer term may be associated with the quasi-orbitals and a first phase factor, and the second layer term may be associated with the quasi-orbitals and a second phase factor different from the first phase factor. The first phase factor and the second phase factor may be associated with the layer-spins of electrons.

In some embodiments, given the spatial positions and spin variables of electrons, spatial information may be transformed to be periodic. This may include the single-particle distance hₑ and the relative distance between two particles hₑₑ′, which may be given by:

$$h = ( r , \vert r \vert ) \to ( {\sum }_{i} {I}_{i} sin ( r \cdot {g}_{i} ) , {\sum }_{i} {I}_{i} cos ( r \cdot {g}_{i} ) , d ( r ) ) , \\ d ( r ) = {\sum }_{ij} sin ( r \cdot {g}_{i} ) sin ( r \cdot {g}_{j} ) {I}_{i} \cdot {I}_{j} + [ 1 - cos ( r \cdot {g}_{i} ) ] [ 1 - cos ( r \cdot {g}_{j} ) ] {I}_{i} \cdot {I}_{j} . \qquad ( 2 )$$

Here l, g denote lattice vectors and reciprocal lattice vectors, respectively. The periodic distance features of different electrons may be then concatenated to form a collective feature vector (i.e., an example distance feature vector), which reads

$${f}_{e}^{α} = concat ( {h}_{e}^{α} , {g}^{↑} , {g}^{↓} , {g}_{e}^{α , ↑} , {g}_{e}^{α , ↓} ) , \\ ( {g}^{↑} , {g}^{↓} ) = ( {Σ}_{e} {h}_{e}^{↑} , {Σ}_{e} {h}_{e}^{↓} ) , \\ ( {g}_{e}^{α , ↑} , {g}_{e}^{α ↓} ) = ( {Σ}_{{e}^{′}} {h}_{{ee}^{′}}^{α ↑} , {Σ}_{{e}^{′}} {h}_{{ee}^{′}}^{α ↓} ) , \qquad ( 3 )$$

where α denotes spin index (↑, ↓). These collective features f may be then passed through a series of fully connected layers to output the quasi-orbitals ϕᵢ(rⱼ; r_{≠j}).

In some embodiments, the neural network output may be doubled to determine the first layer term and the second layer term associated with the layer-spins. For example, the orbitals may be expressed as:

$${ϕ}^{b} ( {r}_{i} ; {r}_{\neq i} ) {e}^{{is}_{i}} + {ϕ}^{t} ( {r}_{i} ; {r}_{\neq i} ) {e}^{- {is}_{i}} \qquad ( 4 )$$

where r_{≠i} denotes all the electron positions except ry. The first layer term (e.g., bottom layer term) may refer to ϕ^{b}(rᵢ; r_{≠i})e^{is}^{ᵢ} where the first phase factor is e^{is}^{ᵢ}. The second layer term (e.g., top layer term) may refer to ϕ^{t}(rᵢ; r_{≠i})e^{-is}^{ᵢ} where the second phase factor is e^{-is}^{ᵢ}.

In some embodiments, for integer fillings, an envelope function e^{ik·r} may be introduced to the orbitals, and all selected k points form a closed shell in Brillouin zone.

In some embodiments, for fractional fillings, all possible k points may be included into considerations and the envelope functions reads Σⱼ πᵢⱼe^{ik}^{ⱼ}^{·r} where π are trainable parameters.

Finally, these orbitals may be combined with a slater determinant to form the final wavefunction,

$$Ψ = det [ {ϕ}_{i}^{↑} ( {r}_{j}^{↑} , {s}_{j}^{↑} ; {r}_{\neq j} , {s}_{\neq j} ) ] det [ {ϕ}_{i}^{↓} ( {r}_{j}^{↓} , {s}_{j}^{↓} ; {r}_{\neq j} , {s}_{\neq j} ) ] , \\ \qquad ( 5 )$$

$${ϕ}_{i} ( {r}_{j} , {s}_{j} ; {r}_{\neq j} , {s}_{\neq j} ) \vert =$$

$$[ {ϕ}_{i}^{b} ( {r}_{j} , {s}_{j} ; {r}_{\neq j} , {s}_{\neq j} ) {e}^{{is}_{j}} + {ϕ}_{i}^{t} ( {r}_{j} , {s}_{j} ; {r}_{\neq j} , {s}_{\neq j} ) {e}^{- {is}_{j}} ] {envelope}_{i} ( {r}_{j} ) .$$

The above framework can be versatile and powerful for studying topological systems across a wide range of materials. As an example, the framework may be applied to tMoTe2, a system that has recently attracted significant attention for hosting various topological phases. The tMoTe2 system features strong spin-valley locking, and its valence band consequently get separated. Its effective Hamiltonian for spin-up electrons may read

$${H}_{↑} = ( \begin{matrix}\frac{{( - i ∇ - {K}_{+} )}^{2}}{2 m} + {Δ}_{b} ( r ) & {Δ}_{T} ( r ) \\ {Δ}_{T}^{*} ( r ) & \frac{{( - i ∇ - {K}_{-} )}^{2}}{2 m} + {Δ}_{t} ( r )\end{matrix} ) , \\ {Δ}_{b / t} ( r ) = - 2 V {Σ}_{i = 1 , 3 , 5} cos ( {g}_{i} \cdot r \pm δ ) , \\ {Δ}_{T} ( r ) = ω ( 1 + {e}^{{ig}_{2} \cdot r} + {e}^{{ig}_{3} \cdot r} ) , \\ {H}_{total} = {H}_{↑} + {H}_{↓} + \frac{1}{2} {Σ}_{i \neq j} \frac{1}{ϵ \vert {r}_{i} - {r}_{j} \vert} \qquad ( 6 )$$

and spin-down Hamiltonian H_{↓} are related by time reversal symmetry. This Hamiltonian exhibits a spinor structure, representing the layer degree of freedom in bilayer systems. Δ_{b} or Δₜ and Δ_{T} denote intra-layer and inter-layer interaction respectively. These potentials form an effective skyrmion field for electrons, which leads to non-trivial topology. Various topological phases are observed experimentally in tMoTe2 systems, which offers an ideal platform to test the proposed solution of the present disclosure.

With the determined wavefunction, whether the moiré system is a topological insulator can be determined. As discussed above, the topological insulator may be a Chern insulator, Z2 insulator, FCI, etc. Properties of different types of topological insulators may be used to determine whether the moiré system is a topological insulator. Note that, various parameter sets of moiré systems may be used to determine respective wavefunctions, and each wavefunction may be used to verify whether the corresponding moiré system is a topological insulator. For example, a first moiré system with specific parameters, e.g., structures may be identified as a topological insulator whereas a second moiré system with different parameters may be identified as not a topological insulator. Examples of the parameters may include a twist angle, intra-layer and inter-layer interaction, etc.

In some embodiments, determining, based on the wavefunction, whether the moiré system is a topological insulator may comprise: determining at least one Chern number based on the wavefunction; and determining whether the moiré system is the topological insulator based on the at least one Chern number.

Topological insulators may be characterized by the presence of robust edge states that enable the transport of particles without scattering, a hallmark of their non-trivial topological properties. Chern number may be the central quantity of the non-trivial topological properties. However, the Chern number is used as a non-limiting example characterizing topological properties of the topological insulators. Any other suitable topological number may be used in the proposed solution of the present disclosure.

In some embodiments, the at least one Chern number may comprise a spin-up Chern number for spin-up electrons and a spin-down Chern number for spin-down electrons. In accordance with a determination that the spin-up Chern number or the spin-down Chern number is a non-zero integer, it may be determined that the moiré system is an integer topological insulator, i.e., topological non-trivial.

In some embodiments, in accordance with the determination that the moiré system is the integer topological insulator and a determination that the electrons are all spin-up or spin-down, it may be determined that the moiré system is a Chern insulator. In accordance with the determination that the moiré system is the integer topological insulator and a determination that half of the electrons are spin-up and half of the electrons are spin-down, it may be determined that the moiré system is a Z2 insulator.

In some examples, Chern number may be given by integrating the many-body Berry curvature F(kₛ) in the supercell Brillouin zone (SBZ):

$$C = \frac{1}{2 π i} {\int }_{SBZ} F ( {k}_{s} ) {dk}_{x} , \\ F ( {k}_{s} ) = {∇}_{{k}_{s}} \times 〈 {Φ}_{{k}_{s}} \vert {∇}_{{k}_{s}} \vert {Φ}_{{k}_{s}} 〉 , \qquad ( 7 )$$

In some examples, the Chern number may be practically calculated using rotation symmetry or the single-point formula without carrying out the integration explicitly. Taking tMoTe2 as an example, the phase diagram of tMoTe2 at integer filling is studied first. In simulations, the real-spin of each particle may be fixed and the ground state may be determined by comparing energies of different spin configurations.

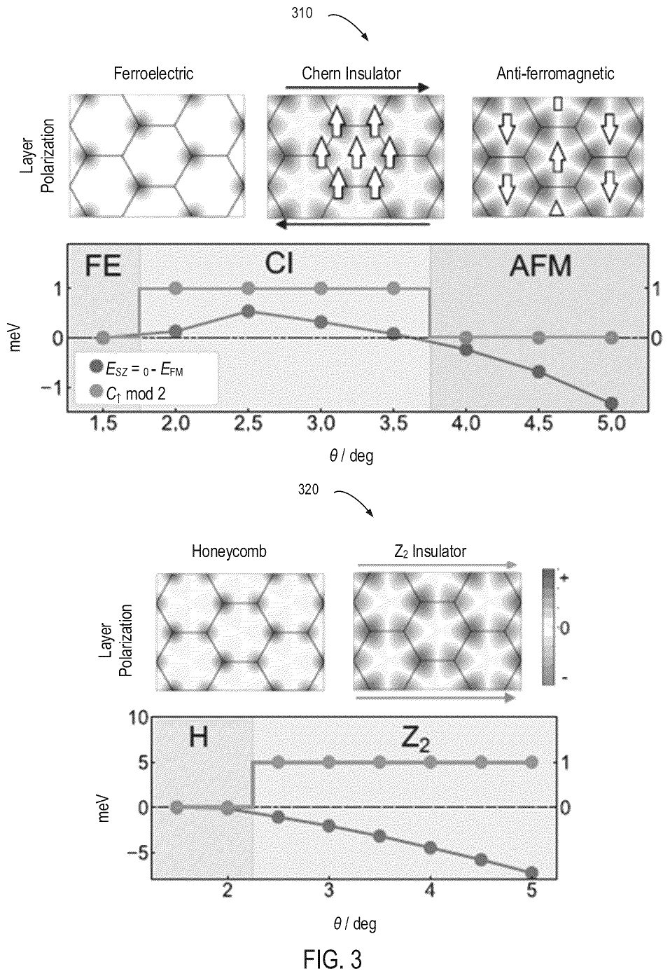

FIG. 3 illustrates examples of calculated phase diagrams of integer topological insulators. FIG. 3 specifically illustrates the calculated phase diagram 310 at n=−1 and the calculated phase diagram 320 at n=−2. Upper panel plots layer polarization density of calculated phases. Arrows in the figure denote the real-spin distribution. Lower panel plots calculated energy difference Eₛ_{_{z}}₌₀−E_{FM} and spin-up Chern number C↑ of ground states at different twist angles.

At filling n=−1, a rectangular primitive cell that contains two holes may be constructed, and the primitive cell may be subsequently tiled to form a 3×3 supercell. As can be seen from the calculated phase diagram 310, ferroelectric states are formed at small twist angle (0)≤1.75°, where electrons accumulate in one layers but show no magnetic order. This behavior results from the dominance of Coulomb interactions at small twist angles, which suppress magnetic effects. As the twist angle increases, time-reversal symmetry is spontaneously broken, leading to the emergence of ferromagnetism and quantum anomalous Hall. In this regime, the system acquires a Chern number of C=1, confirming its topological nature. Further increasing the twist angle results in the disappearance of ferromagnetism and the formation of an anti-ferromagnetic state. Contrast to the 120° Neel order states predicted in some other studies, in the solution of the present disclosure, the real-spins of electrons are fixed in the simulation and instead the formation of a stripe phase is observed, where opposite-spin electrons align into stripes.

At filling n=−2, the system initially forms a honeycomb crystal with no magnetism at small twist angles (see the calculated phase diagram 320). As the twist angle increases, non-trivial topology emerges once again. Unlike the ferromagnetic Chern insulator observed at n=−1, the system retains time-reversal symmetry and becomes a Z2 insulator around θ≃2°, which is consistent with recent experiment results. In this phase, opposite-spin particles propagate in opposite directions along the edges, a signature of the quantum spin Hall effect. The results underscore the effectiveness of the proposed neural network-based approach of the present disclosure, which offers a powerful, scalable tool for identifying topological phases.

In some other embodiments, the determined wavefunction is used to identify whether the moiré system is a FCI. Fractional fillings in topological systems give rise to strong correlations, as all accessible Slater determinants become degenerate in the flat-band limit. This intrinsic degeneracy requires consideration of the full Hilbert space, rendering conventional computational approaches particularly challenging. ED and DMRG methods remain the primary numerical techniques for studying FCI problems, however, their applicability is fundamentally constrained by system size limitations and the complexity of entanglement scaling. As a result, alternative approaches capable of capturing the many-body correlations in FCI are highly desirable.

In the solution of the present disclosure, in some embodiments, a plurality of topological states of the moiré system may be determined based on the wavefunction. In accordance with a determination that the plurality of topological states exhibit three-fold topological degeneracy and that the three-fold topological degeneracy occupies momentum sectors consistent with generalized Pauli principle governing fractional statistics, it may be determined that the moiré system is a FCI.

Additionally, in some embodiments, a symmetric wavefunction that is symmetric to center-of-mass momentum may be determined based on the wavefunction, and the symmetric wavefunction may be used to determine the plurality of topological states to verify whether they exhibit a three-fold topological degeneracy. In some examples, to obtain a full energy spectrum, the proposed neural network of the present disclosure may be symmetrized and a translation symmetric state with different center-of-mass momentum may be constructed.

Periodic systems may have two types of translational symmetries, which reads

$$Ψ ( {r}_{1} + l , … , {r}_{N} + l ) = {e}^{{ik}_{p} \cdot l} Ψ ( {r}_{1} , … , {r}_{N} ) , \\ Ψ ( {r}_{1} + L , … , {r}_{N} ) = {e}^{{ik}_{s} \cdot L} Ψ ( {r}_{1} , … , {r}_{N} ) . \qquad ( 8 )$$

Here, kₛ denotes the twist momentum associated with a translation of any electron by a supercell lattice vector L, and kₚ denotes the center-of-mass momentum corresponding to a simultaneous translation of all electrons by a primitive cell lattice vector L.

In some embodiments, to identify possible FCI states, kₚ-symmetric neural network wavefunctions may be constructed, which may take the form:

$${Ψ}_{{k}_{p}} ( {r}_{1} , … , {r}_{N} ) = {\sum }_{l ∈ supercell} {e}^{{ik}_{p} \cdot l} {Ψ}_{Net} ( {r}_{1} - l , … , {r}_{N} - l ) . \qquad ( 9 )$$

where the summation is constrained in a single supercell, and Ψ_{Net} only possesses supercell translational symmetry. And twist momentum kₛ may be simply fixed by multiplying an overall phase factor e^{ik}^{ₛ}^{·Σ}^{ᵢ}^{r}^{ᵢ}. This construction may provide the most general kₚ symmetric wavefunctions but it requires multiple forward calculation of neural network, which increases computation costs.

Taking tMoTe2 as an example, tMoTe2 systems at fractional filling n=−2/3 are investigated by using the solution of the present disclosure. For simplicity, ferromagnetism is assumed and a 3×4 supercell at θ=2° is used as an example.

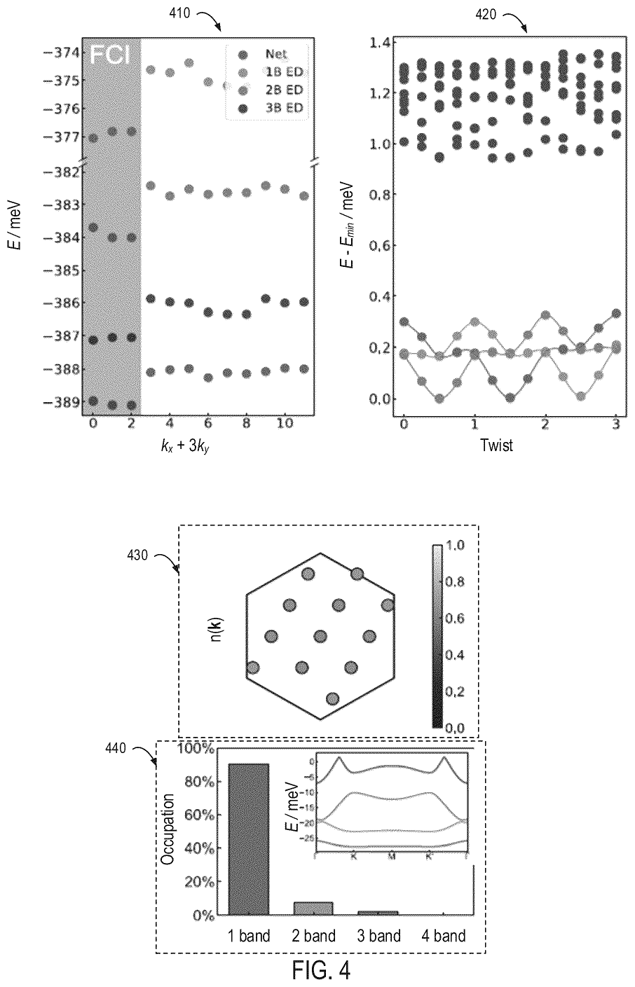

FIG. 4 illustrates examples of calculated energy spectrums of FCI. Specifically, FIG. 4 illustrates an example energy spectrum 410 of FCI at n=−2/3. ED results are plotted for comparison. Ferromagnetic is assumed and 3×4 supercell is used at θ=2°. The shadowed region highlights the three degenerate FCI states. FIG. 4 further illustrates an example energy spectrum 420 for different twist boundary conditions. The three FCI states remain gapped from the higher-lying excited states. As twist is increased, the three FCI states mix with each other.

FIG. 4 further illustrates calculated one-body density matrix [symbol] n(k) [symbol] 430 at different momentum. Averaging [symbol] n(k) [symbol] over three degenerated FCI states may reveal nearly uniform distributions. FIG. 4 further illustrates band structure analysis 440 of the neural network wavefunction. Multi-band orbitals may be included in the neural network representation. Moreover, the inset plots corresponding band structure of tMoTe2.

The results, presented in FIG. 4, may reveal that the ground state exhibits a three-fold topological degeneracy, with the degenerate states occupying momentum sectors consistent with the generalized Pauli principle governing fractional statistics.

Moreover, as illustrated in FIG. 4, the obtained energy spectrums are compared with ED results to assess the accuracy of the proposed neural network approach of the present disclosure. As can be seen from the figure, the determined neural network wavefunction in the present disclosure yields energies that outperform even three-band ED calculations, which are already at the computational limits of traditional methods. Furthermore, the threefold degeneracy of the ground state is preserved across different twist boundary conditions, with the states gapped from higher-energy excitations. Additionally, the near-uniform density distribution of these states across the Brillouin zone further substantiates their identification as a FCI phase. And the orbital analysis 440 in FIG can reveal that the neural network wavefunction encompasses multiple bands, highlighting the method's capability to capture band-mixing and achieve high accuracy.

Moving forward, the competition between charge density wave (CDW) and FCI phases at fractional fillings is explored, as both of them can exhibit similar ground state degeneracies but differ in their topological properties. While FCI states have been observed in moiré materials, many anticipated FCI phases turn out to be CDW states instead. This raises the question of how to distinguish these phases and determine the precise conditions under which each emerges.

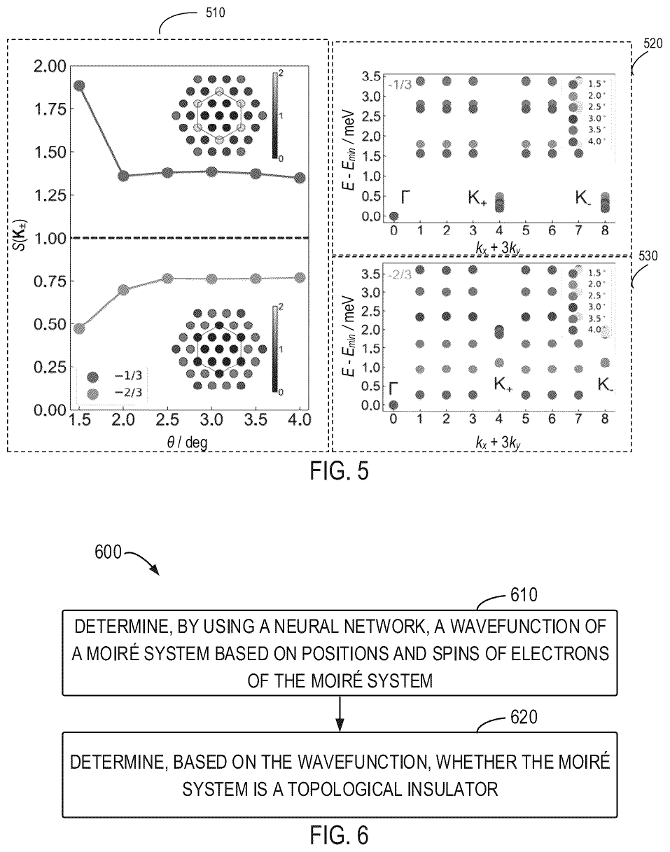

To address this, two representative filling factors, n=−1/3 and −2/3, are studied and corresponding results are presented in FIG. 5. FIG. 5 illustrates example results of FCI-CDW competing. Specifically, FIG. 5 illustrates structure factor peak S(K_{±}) 510 of Γ state at different twist angles and fillings. The inset plots the structure factor at different momentums. FIG. 5 further illustrates the calculated energy spectrum 520 of fillings n=−1/3 and the calculated energy spectrum 530 of fillings n=−2/3 at different twist angles. In the example of FIG. 5, 3×3 supercell is used.

As can be seen from FIG. 5, for n=−1/3, a nearly threefold degenerate ground state across a broad range of twist angles can be observed, with associated momenta located at Γ, K+ and K−. This degeneracy and the corresponding momentum distribution are clear signatures of a CDW state. Additionally, the structure factor for this phase reveals sharp peaks at K+, further confirming the presence of a CDW ordering. Notably, these results differ from earlier ED calculations, which predicted the emergence of FCI states at small twist angles (typically for θ≤2°. In contrast, in the present disclosure, it is found that CDW states persist even at smaller twist angles. This discrepancy may be attributed to the inclusion of higher-band effects in the proposed approach of the present disclosure, as the proposed neural network wavefunction captures multiple bands, underscoring the enhanced accuracy of our method.

For n=−2/3, a distinctly different behavior is illustrated in FIG. 5. The I state is found to be gaped from all other states, and its structure factor evolves smoothly without exhibiting sharp peaks. This continuous behavior in the structure factor rules out the possibility of a CDW and instead supports the existence of robust FCI states.

In the present disclosure, a novel deep learning QMC approach is introduced to simulate topological insulators, leveraging neural networks to represent many-body wavefunctions. This method combines the strengths of neural networks—capable of capturing complex, strongly correlated systems—with the precision and efficiency of QMC techniques.

As a non-limiting example, by applying this approach to tMoTe2, a variety of topological phases can be successfully identified and characterized, including Chern insulators and Z2 insulators, at both integer and fractional fillings. The results further demonstrate superior accuracy compared to traditional ED methods, while maintaining significantly lower computational complexity.

This advancement represents a significant leap forward in the deep learning study of topological physics. The ability to accurately simulate systems at fractional fillings, where strong correlations and non-trivial topology present formidable challenges, opens new avenues for exploring exotic quantum phases. The proposed method of the present disclosure not only provides a robust framework for identifying topological states but also offers insights into the competition between different phases, such as FCI and CDW. This capability is crucial for understanding the intricate interplay between topology and strong correlations in moiré materials.

Looking ahead, the versatility of the neural network-based approach of the present disclosure holds great promise for investigating other complex topological phenomena. For instance, it could be applied to study anyon statistics, unconventional superconductivity. Furthermore, the scalability of the proposed method makes it a valuable tool for exploring larger systems and higher-dimensional topological materials, which are beyond the reach of traditional computational techniques.

In the following, supplementary information of the proposed method of the present disclosure is given.

### A. Moiré Hamiltonian

Moiré systems contains numerous electrons, which makes ab-initio calculation impractical. Effective continuum model is usually derived to simplify the problem, which only considers the most active valence electrons. For tMoTe2 systems, a two-component Hamiltonian may be constructed for each spin channel, accounting for the orbitals in the top and bottom layer respectively. And the periodic potential term Δ may read

$${Δ}_{b / t} ( r ) = - 2 V {\sum }_{i = 1 , 3 , 5} cos ( {g}_{i} \cdot r \pm δ ) , \\ {Δ}_{T} ( r ) = ω ( 1 + {e}^{{ig}_{2} \cdot r} + {e}^{{ig}_{3} \cdot r} ) , \qquad ( 10 )$$

where

$${g}_{i} = \frac{4 π}{\sqrt{3} {a}_{M}} ( cos ( \frac{π ( i - 1 )}{3} ) , sin ( \frac{π ( i - 1 )}{3} ) )$$

are the primitive cell reciprocal lattice vectors and V, ω, δ are parameters fitted from density functional results.

### B. Continuous Spin

The two-component Hamiltonian for tMoTe2 does not commute with the z-component of the layer-spin, implying that the layer-spin of each particle must be treated as a dynamic variable. Simultaneously handling of continuous spatial variables r and discrete spin variables s_{z} may introduce sampling challenges in quantum Monte Carlo. To address this, the continuous spin technique may be employed, which takes the form:

$$ϕ ( r , s ) = {ϕ}^{b} ( r ) {e}^{is} + {ϕ}^{t} ( r ) {e}^{- is} , \qquad ( 11 )$$

where s is a continuous layer-spin variable constrained to the interval [0, 2π]. And the single-particle orbitals ϕ^{b/t}(rᵢ) are promoted by neural network orbitals ϕ_{b/t}(rᵢ; r_{≠i}) as discussed above.

### C. Many-Body Topological Invariants

The definition of the many-body Chern number typically requires an integration over the supercell Brillouin zone, which can be impractical. To overcome this, the single-point formula may be employed, which may read

$${ρ}_{σ} = \frac{〈 Ψ \vert {Z}_{σ} ( {G}_{1} + {G}_{2} ) \vert Ψ 〉}{〈 Ψ \vert {Z}_{σ} ( {G}_{1} ) \vert Ψ 〉 〈 Ψ \vert {Z}_{σ} ( {G}_{2} ) \vert Ψ 〉} , \\ {Z}_{σ} ( G ) = {e}^{iG \cdot {\sum }_{i} {r}_{i}^{σ}} , \qquad ( 12 )$$

where G denotes supercell reciprocal lattice vectors and σ denotes each spin channel. It can be proved that the phase angle of ρ_{σ} reduced to Chern number at thermo-dynamic limit (TDL), which reads Arg[ρ_{σ}]/π⇒C_{σ}mod2. Eq. (12) only requires a single many-body wavefunction which efficiently determines Chern number up to modulus 2.

### D. Expectation Formula

Continuous spin techniques may be used to express layer-spin, and neural network may be employed to express spatial part. For tMoTe2 Hamiltonian, the neural network wavefunction may read

$${Ψ}_{Net} ( R , S ) = \qquad ( 13 )$$

$$det \vert \begin{matrix}{ϕ}_{1}^{b} ( {r}_{1} ; {r}_{\neq 1} ) {e}^{{is}_{1}} + {ϕ}_{1}^{t} ( {r}_{1} ; {r}_{\neq 1} ) {e}^{- {is}_{1}} & … & {ϕ}_{N}^{b} ( {r}_{1} ; {r}_{\neq 1} ) {e}^{{is}_{1}} + {ϕ}_{N}^{1} ( {r}_{1} ; {r}_{\neq 1} ) {e}^{- {is}_{1}} \\ ⋮ & & ⋮ \\ ⋮ & & ⋮ \\ \begin{matrix}{ϕ}_{1}^{b} ( {r}_{N} ; {r}_{\neq N} ) {e}^{{is}_{N}} + \\ {ϕ}_{1}^{t} ( {r}_{N} ; {r}_{\neq N} ) {e}^{- {is}_{N}}\end{matrix} & … & \begin{matrix}{ϕ}_{N}^{b} ( {r}_{N} ; {r}_{\neq N} ) {e}^{{is}_{N}} + \\ {ϕ}_{N}^{t} ( {r}_{N} ; {r}_{\neq N} ) {e}^{- {is}_{N}}\end{matrix}\end{matrix} \vert$$

The expectation formula of layer-spin Σᵢ σᵢ^{a} (a=x, y, z) may read

$$\frac{〈 Ψ \vert {Σ}_{i} {σ}_{i}^{a} \vert Ψ 〉}{〈 Ψ \vert Ψ 〉} = \int {dx}_{1} {dx}_{2} … {dx}_{N} {\sum }_{i} {\vert Ψ \vert}^{2} \frac{{Ψ}_{i}^{a} ( {x}_{1} , … , {x}_{N} )}{Ψ ( {x}_{1} , … , {x}_{N} )} , \qquad ( 14 )$$

where x denotes position r and layer-spin s together. Ψᵢ^{a} denotes the original wavefunction except its i-th row is modified by layer-spin operator σ^{a}. The specific formula may read

$${Ψ}_{1}^{x} ( R , S ) = \qquad ( 15 )$$

$$det \vert \begin{matrix}{ϕ}_{1}^{t} ( {r}_{1} ; {r}_{\neq 1} ) {e}^{{is}_{1}} + {ϕ}_{1}^{b} ( {r}_{1} ; {r}_{\neq 1} ) {e}^{- {is}_{1}} & … & {ϕ}_{N}^{t} ( {r}_{1} ; {r}_{\neq 1} ) {e}^{{is}_{1}} + {ϕ}_{N}^{b} ( {r}_{1} ; {r}_{\neq 1} ) {e}^{- {is}_{1}} \\ ⋮ & & ⋮ \\ ⋮ & & ⋮ \\ \begin{matrix}{ϕ}_{1}^{b} ( {r}_{N} ; {r}_{\neq N} ) {e}^{{is}_{N}} + \\ {ϕ}_{1}^{t} ( {r}_{N} ; {r}_{\neq N} ) {e}^{- {is}_{N}}\end{matrix} & … & \begin{matrix}{ϕ}_{N}^{b} ( {r}_{N} ; {r}_{\neq N} ) {e}^{{is}_{N}} + \\ {ϕ}_{N}^{t} ( {r}_{N} ; {r}_{\neq N} ) {e}^{- {is}_{N}}\end{matrix}\end{matrix} \vert$$

$${Ψ}_{1}^{y} ( R , S ) = det \vert \begin{matrix}\begin{matrix}- i {ϕ}_{1}^{t} ( {r}_{1} ; {r}_{\neq 1} ) {e}^{{is}_{1}} + \\ i {ϕ}_{1}^{b} ( {r}_{1} ; {r}_{\neq 1} ) {e}^{- {is}_{1}}\end{matrix} & … & \begin{matrix}- i {ϕ}_{N}^{t} ( {r}_{1} ; {r}_{\neq 1} ) {e}^{{is}_{1}} + \\ i {ϕ}_{N}^{b} ( {r}_{1} ; {r}_{\neq 1} ) {e}^{- {is}_{1}}\end{matrix} \\ ⋮ & & ⋮ \\ \begin{matrix}{ϕ}_{1}^{b} ( {r}_{N} ; {r}_{\neq N} ) {e}^{{is}_{N}} + \\ {ϕ}_{1}^{t} ( {r}_{N} ; {r}_{\neq N} ) {e}^{- {is}_{N}}\end{matrix} & … & \begin{matrix}{ϕ}_{N}^{b} ( {r}_{N} ; {r}_{\neq N} ) {e}^{{is}_{N}} + \\ {ϕ}_{N}^{t} ( {r}_{N} ; {r}_{\neq N} ) {e}^{- {is}_{N}}\end{matrix}\end{matrix} \vert ,$$

$${Ψ}_{1}^{z} ( R , S ) = det \vert \begin{matrix}{ϕ}_{1}^{b} ( {r}_{1} ; {r}_{\neq 1} ) {e}^{{is}_{1}} - {ϕ}_{1}^{t} ( {r}_{1} ; {r}_{\neq 1} ) {e}^{- {is}_{1}} & … & {ϕ}_{N}^{b} ( {r}_{1} ; {r}_{\neq 1} ) {e}^{{is}_{1}} - {ϕ}_{N}^{t} ( {r}_{1} ; {r}_{\neq 1} ) {e}^{- {is}_{1}} \\ ⋮ & & ⋮ \\ \begin{matrix}{ϕ}_{1}^{b} ( {r}_{N} ; {r}_{\neq N} ) {e}^{{is}_{N}} + \\ {ϕ}_{1}^{t} ( {r}_{N} ; {r}_{\neq N} ) {e}^{- {is}_{N}}\end{matrix} & … & \begin{matrix}{ϕ}_{N}^{b} ( {r}_{N} ; {r}_{\neq N} ) {e}^{{is}_{N}} + \\ {ϕ}_{N}^{t} ( {r}_{N} ; {r}_{\neq N} ) {e}^{- {is}_{N}}\end{matrix}\end{matrix} \vert .$$

Since only one raw of determinant is modified, fast-update method can be used to accelerate the calculation.

For spin-orbital coupling term Σ_{i,a} σᵢ^{a}·∇ᵢ^{a}, the formula may read

$$\frac{〈 Ψ \vert {Σ}_{i , a} {σ}_{i}^{a} \cdot {∇}_{i}^{a} \vert Ψ 〉}{〈 Ψ \vert Ψ 〉} = \int {dx}_{1} {dx}_{2} … {dx}_{N} {\sum }_{i , a} {\vert Ψ \vert}^{2} \frac{{∇}_{i}^{a} {Ψ}_{i}^{a} ( {x}_{1} , … , {x}_{N} )}{Ψ ( {x}_{1} , … , {x}_{N} )} . \qquad ( 16 )$$

### E. Workflow and Computational Details

Supercell approximation may be employed in the simulations. Spatial positions and continuous spins may be uniformly initialized. The expectations of operators may be evaluated via the Monte Carlo approach. Forward Laplacian technique may be employed to speed up the simulation. The simulations may be performed on eight A800 graphics processing units within several hours.

### Example Process and Device

FIG. 6 illustrates a flowchart of a method 600 for a deep learning simulation of a topological insulator in accordance with some example implementations of the present disclosure. The method 600 may be implemented by any suitable device with computing capability, for example, a processor.

In the method 600, at block 610, a wavefunction of a moiré system is determined by using a neural network based on positions and spins of electrons of the moiré system. At block 620, whether the moiré system is a topological insulator is determined based on the wavefunction.

In some embodiments, the spins comprise layer-spins and real-spins, and determining, by using the neural network, the wavefunction of the moiré system comprises: determining a distance feature vector based on the positions of electrons; determining quasi-orbitals of the moiré system based on the distance feature vector; and determining the wavefunction based on a first layer term and a second layer term, the first layer term associated with the quasi-orbitals and a first phase factor, the second layer term associated with the quasi-orbitals and a second phase factor different from the first phase factor, the first phase factor and the second phase factor.

In some embodiments, the method further comprises: determining a ground state of the wavefunction by using Quantum Monte Carlo; and where determining, based on the wavefunction, whether the moiré system is a topological insulator is based on the ground state.

In some embodiments, determining, based on the wavefunction, whether the moiré system is a topological insulator comprises: determining at least one Chern number based on the wavefunction; and determining whether the moiré system is the topological insulator based on the at least one Chern number.

In some embodiments, wherein the at least one Chern number comprises a spin-up Chern number for spin-up electrons and a spin-down Chern number for spin-down electrons, and the method further comprises: in accordance with a determination that the spin-up Chern number or the spin-down Chern number is a non-zero integer, determining that the moiré system is the topological insulator.

In some embodiments, the method further comprises: in accordance with the determination that the moiré system is the topological insulator and a determination that the electrons are all spin-up or spin-down, determining that the moiré system is a Chern insulator; and in accordance with the determination that the moiré system is the topological insulator and a determination that half of the electrons are spin-up and half of the electrons are spin-down, determining that the moiré system is a Z2 insulator.

In some embodiments, determining, based on the wavefunction, whether the moiré system is a topological insulator comprises: determining, a plurality of topological states of the moiré system based on the wavefunction; and in accordance with a determination that the plurality of topological states exhibit three-fold topological degeneracy and that the three-fold topological degeneracy occupies momentum sectors consistent with generalized Pauli principle governing fractional statistics, determining that the moiré system is a fractional Chern insulator (FCI).

In some embodiments, determining, the plurality of topological states based on the wavefunction comprises: determining, based on the wavefunction, a symmetric wavefunction that is symmetric to center-of-mass momentum; and determining, the plurality of topological states based on the symmetric wavefunction.

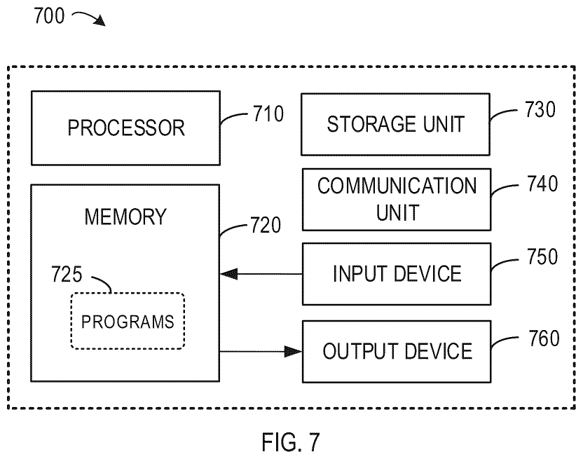

FIG. 7 illustrates a block diagram of an electronic device 700 in which various embodiments of the present disclosure can be implemented. It would be appreciated that the electronic device 700 shown in FIG. 7 is merely for purpose of illustration, without suggesting any limitation to the functions and scopes of the present disclosure in any manner. The electronic device 700 may be used to implement the above method 700. As shown in FIG. 7, the electronic device 700 may be a general-purpose electronic device. The electronic device 700 may at least comprise one or more processors or processing units 710, a memory 720, a storage unit 730, one or more communication units 740, one or more input devices 750, and one or more output devices 760.

The processor 710 may be a physical or virtual processor and can implement various processes based on programs 725 stored in the memory 720. In a multi-processor system, multiple processing units execute computer executable instructions in parallel so as to improve the parallel processing capability of the electronic device 700. The processor 710 may also be referred to as a central processing unit (CPU), a microprocessor, a controller, or a microcontroller.

The electronic device 700 typically includes various computer storage medium. Such medium can be any medium accessible by the electronic device 700, including, but not limited to, volatile and non-volatile medium, or detachable and non-detachable medium. The memory 720 can be a volatile memory (for example, a register, cache, Random Access Memory (RAM)), a non-volatile memory (such as a Read-Only Memory (ROM), Electrically Erasable Programmable Read-Only Memory (EEPROM), or a flash memory), or any combination thereof. The storage unit 730 may be any detachable or non-detachable medium and may include a machine-readable medium such as a memory, flash memory drive, magnetic disk, or another other media, which can be used for storing information and/or data and can be accessed in the electronic device 700.

The electronic device 700 may further include additional detachable/non-detachable, volatile/non-volatile memory medium. Although not shown in FIG. 7, it is possible to provide a magnetic disk drive for reading from and/or writing into a detachable and non-volatile magnetic disk and an optical disk drive for reading from and/or writing into a detachable non-volatile optical disk. In such cases, each drive may be connected to a bus (not shown) via one or more data medium interfaces.

The communication unit 740 communicates with a further electronic device via the communication medium. In addition, the functions of the components in the electronic device 700 can be implemented by a single computing cluster or multiple computing machines that can communicate via communication connections. Therefore, the electronic device 700 can operate in a networked environment using a logical connection with one or more other servers, networked personal computers (PCs) or further general network nodes.

The input device 750 may be one or more of a variety of input devices, such as a mouse, keyboard, tracking ball, voice-input device, and the like. The output device 760 may be one or more of a variety of output devices, such as a display, loudspeaker, printer, and the like. By means of the communication unit 740, the electronic device 700 can further communicate with one or more external devices (not shown) such as the storage devices and display device, with one or more devices enabling the user to interact with the electronic device 700, or any devices (such as a network card, a modem, and the like) enabling the electronic device 700 to communicate with one or more other electronic devices, if required. Such communication can be performed via input/output (I/O) interfaces (not shown).

In some embodiments, instead of being integrated in a single device, some, or all components of the electronic device 700 may also be arranged in cloud computing architecture. In the cloud computing architecture, the components may be provided remotely and work together to implement the functionalities described in the present disclosure. In some embodiments, cloud computing provides computing, software, data access and storage service, which will not require end users to be aware of the physical locations or configurations of the systems or hardware providing these services. In various embodiments, the cloud computing provides the services via a wide area network (such as Internet) using suitable protocols. For example, a cloud computing provider provides applications over the wide area network, which can be accessed through a web browser or any other computing components. The software or components of the cloud computing architecture and corresponding data may be stored on a server at a remote position. The computing resources in the cloud computing environment may be merged or distributed at locations in a remote data center. Cloud computing infrastructures may provide the services through a shared data center, though they behave as a single access point for the users. Therefore, the cloud computing architectures may be used to provide the components and functionalities described herein from a service provider at a remote location. Alternatively, they may be provided from a conventional server or installed directly or otherwise on a client device.

The functionalities described herein can be performed, at least in part, by one or more hardware logic components. For example, and without limitation, illustrative types of hardware logic components that can be used include Field-Programmable Gate Arrays (FPGAs), Application-specific Integrated Circuits (ASICs), Application-specific Standard Products (ASSPs), System-on-a-chip systems (SOCs), Complex Programmable Logic Devices (CPLDs), and the like.

Program code for carrying out the methods of the subject matter described herein may be written in any combination of one or more programming languages. The program code may be provided to a processor or controller of a general-purpose computer, special purpose computer, or other programmable data processing apparatus such that the program code, when executed by the processor or controller, causes the functions/operations specified in the flowcharts and/or block diagrams to be implemented. The program code may be executed entirely or partly on a machine, executed as a stand-alone software package partly on the machine, partly on a remote machine, or entirely on the remote machine or server.

In the context of this disclosure, a machine-readable medium may be any tangible medium that may contain or store a program for use by or in connection with an instruction execution system, apparatus, or device. The machine-readable medium may be a machine-readable signal medium or a machine-readable storage medium. A machine-readable medium may include but not limited to an electronic, magnetic, optical, electromagnetic, infrared, or semiconductor system, apparatus, or device, or any suitable combination of the foregoing. More specific examples of the machine-readable storage medium would include an electrical connection having one or more wires, a portable computer diskette, a hard disk, a random-access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Further, while operations are illustrated in a particular order, this should not be understood as requiring that such operations are performed in the particular order shown or in sequential order, or that all illustrated operations are performed to achieve the desired results. In certain circumstances, multitasking and parallel processing may be advantageous. Likewise, while several specific implementation details are contained in the above discussions, these should not be construed as limitations on the scope of the subject matter described herein, but rather as descriptions of features that may be specific to particular embodiments. Certain features that are described in the context of separate embodiments may also be implemented in combination in a single implementation. Rather, various features described in a single implementation may also be implemented in multiple embodiments separately or in any suitable sub-combination.

Although the subject matter has been described in language specific to structural features and/or methodological acts, it is to be understood that the subject matter specified in the appended claims is not necessarily limited to the specific features or acts described above. Rather, the specific features and acts described above are disclosed as example forms of implementing the claims.

From the foregoing, it will be appreciated that specific embodiments of the presently disclosed technology have been described herein for purposes of illustration, but that various modifications may be made without deviating from the scope of the disclosure. Accordingly, the presently disclosed technology is not limited except as by the appended claims.

Embodiments of the subject matter and the functional operations described in the present disclosure can be implemented in various systems, digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of nonvolatile memory, media, and memory devices, including by way of example semiconductor memory devices, e.g., EPROM, EEPROM, and flash memory devices. The processor and the memory can be supplemented by, or incorporated in, special purpose logic circuitry.

It is intended that the specification, together with the drawings, be considered exemplary only, where exemplary means an example. As used herein, the use of “or” is intended to include “and/or”, unless the context clearly indicates otherwise.

While the present disclosure contains many specifics, these should not be construed as limitations on the scope of any disclosure or of what may be claimed, but rather as descriptions of features that may be specific to particular embodiments of particular disclosures. Certain features that are described in the present disclosure in the context of separate embodiments can also be implemented in combination in a single implementation. Conversely, various features that are described in the context of a single implementation can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are illustrated in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments. Only a few embodiments and examples are described and other embodiments, enhancements and variations can be made based on what is described and illustrated in the present disclosure.

What is claimed is:

1. A method for a deep learning simulation of a topological insulator, comprising:
determining, by using a neural network, a wavefunction of a moiré system based on positions and spins of electrons of the moiré system; and
determining, based on the wavefunction, whether the moiré system is a topological insulator.

2. The method of claim 1, wherein the spins comprise layer-spins and real-spins, and determining, by using the neural network, the wavefunction of the moiré system comprises:
determining a distance feature vector based on the positions of electrons;
determining quasi-orbitals of the moiré system based on the distance feature vector; and
determining the wavefunction based on a first layer term and a second layer term, the first layer term associated with the quasi-orbitals and a first phase factor, the second layer term associated with the quasi-orbitals and a second phase factor different from the first phase factor, the first phase factor and the second phase factor.

3. The method of claim 1, further comprising:
determining a ground state of the wavefunction by using Quantum Monte Carlo; and
where determining, based on the wavefunction, whether the moiré system is a topological insulator is based on the ground state.

4. The method of claim 1, wherein determining, based on the wavefunction, whether the moiré system is a topological insulator comprises:
determining at least one Chern number based on the wavefunction; and
determining whether the moiré system is the topological insulator based on the at least one Chern number.

5. The method of claim 4, wherein the at least one Chern number comprises a spin-up Chern number for spin-up electrons and a spin-down Chern number for spin-down electrons, and the method further comprises:
in accordance with a determination that the spin-up Chern number or the spin-down Chern number is a non-zero integer, determining that the moiré system is the topological insulator.

6. The method of claim 5, further comprising:
in accordance with the determination that the moiré system is the topological insulator and a determination that the electrons are all spin-up or spin-down, determining that the moiré system is a Chern insulator; and
in accordance with the determination that the moiré system is the topological insulator and a determination that half of the electrons are spin-up and half of the electrons are spin-down, determining that the moiré system is a Z2 insulator.

7. The method of claim 1, wherein determining, based on the wavefunction, whether the moiré system is a topological insulator comprises:
determining, a plurality of topological states of the moiré system based on the wavefunction; and
in accordance with a determination that the plurality of topological states exhibit three-fold topological degeneracy and that the three-fold topological degeneracy occupies momentum sectors consistent with generalized Pauli principle governing fractional statistics, determining that the moiré system is a fractional Chern insulator (FCI).

8. The method of claim 5, wherein determining, the plurality of topological states based on the wavefunction comprises:
determining, based on the wavefunction, a symmetric wavefunction that is symmetric to center-of-mass momentum; and
determining the plurality of topological states based on the symmetric wavefunction.

9. An electronic device, comprising a computer processor coupled to a computer-readable memory unit, the memory unit comprising instructions that when executed by the computer processor implement operations for a deep learning simulation of a topological insulator, the operations comprising:
determining, by using a neural network, a wavefunction of a moiré system based on positions and spins of electrons of the moiré system; and
determining, based on the wavefunction, whether the moiré system is a topological insulator.

10. The device of claim 9, wherein the spins comprise layer-spins and real-spins, and determining, by using the neural network, the wavefunction of the moiré system comprises:
determining a distance feature vector based on the positions of electrons;
determining quasi-orbitals of the moiré system based on the distance feature vector; and
determining the wavefunction based on a first layer term and a second layer term, the first layer term associated with the quasi-orbitals and a first phase factor, the second layer term associated with the quasi-orbitals and a second phase factor different from the first phase factor, the first phase factor and the second phase factor.

11. The device of claim 9, the operations further comprising:
determining a ground state of the wavefunction by using Quantum Monte Carlo; and
where determining, based on the wavefunction, whether the moiré system is a topological insulator is based on the ground state.

12. The device of claim 9, wherein determining, based on the wavefunction, whether the moiré system is a topological insulator comprises:
determining at least one Chern number based on the wavefunction; and
determining whether the moiré system is the topological insulator based on the at least one Chern number.

13. The device of claim 12, wherein the at least one Chern number comprises a spin-up Chern number for spin-up electrons and a spin-down Chern number for spin-down electrons, and the operations further comprise:
in accordance with a determination that the spin-up Chern number or the spin-down Chern number is a non-zero integer, determining that the moiré system is the topological insulator.

14. The device of claim 13, the operations further comprising:
in accordance with the determination that the moiré system is the topological insulator and a determination that the electrons are all spin-up or spin-down, determining that the moiré system is a Chern insulator; and
in accordance with the determination that the moiré system is the topological insulator and a determination that half of the electrons are spin-up and half of the electrons are spin-down, determining that the moiré system is a Z2 insulator.

15. The device of claim 9, wherein determining, based on the wavefunction, whether the moiré system is a topological insulator comprises:
determining, a plurality of topological states of the moiré system based on the wavefunction; and
in accordance with a determination that the plurality of topological states exhibit three-fold topological degeneracy and that the three-fold topological degeneracy occupies momentum sectors consistent with generalized Pauli principle governing fractional statistics, determining that the moiré system is a fractional Chern insulator (FCI).

16. The device of claim 15, wherein determining, the plurality of topological states based on the wavefunction comprises:
determining, based on the wavefunction, a symmetric wavefunction that is symmetric to center-of-mass momentum; and
determining, the plurality of topological states based on the symmetric wavefunction.

17. A computer program product, the computer program product comprising a non-transitory computer readable storage medium having program instructions embodied therewith, the program instructions executable by an electronic device to cause the electronic device to perform operations comprising:
determining, by using a neural network, a wavefunction of a moiré system based on positions and spins of electrons of the moiré system; and
determining, based on the wavefunction, whether the moiré system is a topological insulator.

18. The computer program product of claim 17, wherein the spins comprise layer-spins and real-spins, and determining, by using the neural network, the wavefunction of the moiré system comprises:
determining a distance feature vector based on the positions of electrons;
determining quasi-orbitals of the moiré system based on the distance feature vector; and
determining the wavefunction based on a first layer term and a second layer term, the first layer term associated with the quasi-orbitals and a first phase factor, the second layer term associated with the quasi-orbitals and a second phase factor different from the first phase factor, the first phase factor and the second phase factor.

19. The computer program product of claim 17, the operations further comprising:
determining a ground state of the wavefunction by using Quantum Monte Carlo; and
where determining, based on the wavefunction, whether the moiré system is a topological insulator is based on the ground state.

20. The computer program product of claim 17, wherein determining, based on the wavefunction, whether the moiré system is a topological insulator comprises:
determining at least one Chern number based on the wavefunction; and
determining whether the moiré system is the topological insulator based on the at least one Chern number.
